(19) United States
(12) Patent Application Publication
(10) Pub. No.: US 2013/0228878 A1
(43) Pub. Date: Sep. 5, 2013

(54) POLY RESISTOR DESIGN FOR REPLACEMENT GATE TECHNOLOGY

(71) Applicants: Pai-Chieh WANG, Zhubei City (TW); Yimin HUANG, Hsinchu City (TW)

(72) Inventors: Pai-Chieh WANG, Zhubei City (TW); Yimin HUANG, Hsinchu City (TW)

(73) Assignee: TAIWAN SEMICONDUCTOR MANUFACTURING COMPANY, LTD., Hsinchu (TW)

(21) Appl. No.: 13/411,127

(22) Filed: Mar. 2, 2012

(51) Int. Cl. H01L 29/78; H01L 21/76

(52) U.S. Cl. 257/410; 438/400; 257/E29.255; 257/E21.54

(57) ABSTRACT

A semiconductor device and method for fabricating a semiconductor device are disclosed. The semiconductor device comprises a semiconductor substrate; an active region of the substrate, wherein the active region includes at least one transistor; and a passive region of the substrate, wherein the passive region includes at least one resistive structure disposed on an isolation region, the at least one resistive structure in a lower plane than the at least one transistor

### BACKGROUND

Recently the use of metal material as the gate conductors with high-k gate dielectrics has become more prevalent in “high-k metal gate” or “HKMG” semiconductor processes. As the metal gate conductors lie over a dielectric layer, MOS capacitors may be formed by using the metal gate conductor of the HKMG device as a first plate, the high-k dielectric material as the capacitor dielectric, and the second plate may be formed beneath the dielectric, for example by doping the substrate to form a conductive region. In this manner metal gate MOS capacitors may be formed in a HKMG replacement gate process. The metal gate material may be formed in a replacement gate process by replacing a previously formed dummy gate. The dummy gates are formed earlier in the process and may be used for certain process steps. Then, using photolithography pattern and etch steps to remove the dummy gates and the original gate dielectric, the replacement gate process exposes a gate trench area in an interlevel dielectric layer. High-k dielectrics may be used to form the dielectric in the replacement gate region. The metal replacement gate can be formed in a variety of ways, for example by deposition or plating, and then removing excess metal in a chemical mechanical polishing (CMP) process.

One consequence of the above replacement gate process is that the polysilicon resistors need to be shielded during the process of replacing the dummy gates with high-k metal gate material. Protecting the polysilicon resistors during the gate replacement process would require additional hard masks and photolithographic steps. This adds additional cost and incurs additional processing time.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for only illustration purposes. In fact, the dimensions of the various features may be arbitrarily increased or reduced for clarity of discussion.

FIG. 1 is a flow chart of a method for forming a semiconductor device according to aspects of the present disclosure.

FIGS. 2-11 are various cross-sectional views of embodiments of a semiconductor device during various fabrication stages made by the method of FIG. 1.

### DETAILED DESCRIPTION

The present disclosure relates generally to the field of semiconductor devices and, more particularly, to a method for fabricating a semiconductor device including a polysilicon resistor in a “high-k metal gate” or “HKMG” replacement gate process.

It is understood that the following description provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

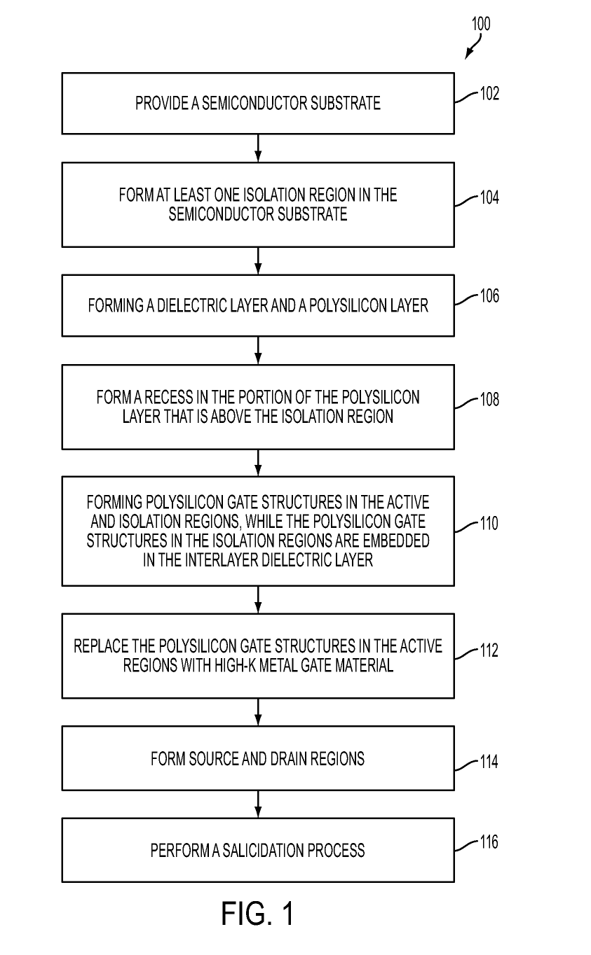

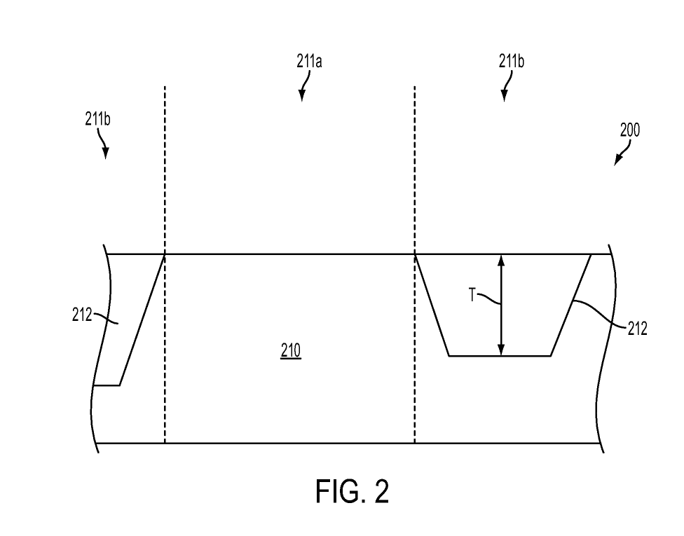

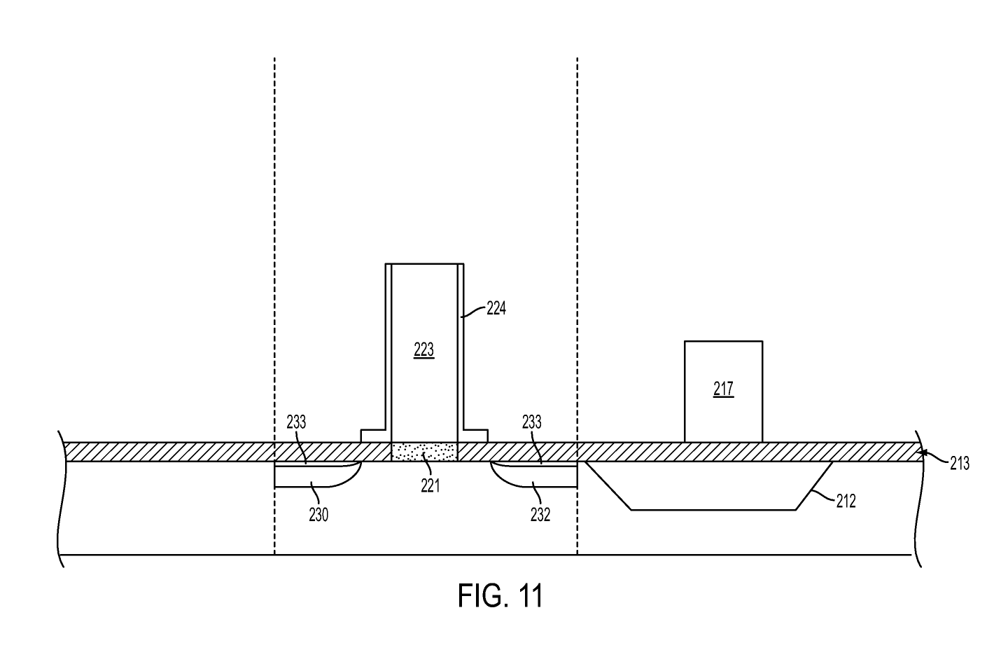

With reference to FIGS. 1 through 11, a method 100 and a semiconductor device 200 are collectively described below. FIG. 1 is a flow chart of one embodiment of the method 100 for making the semiconductor device 200. FIGS. 2-10 are various cross-sectional views of the semiconductor device 200 according to one embodiment, in portion or entirety, during various fabrication stages of the method 100. FIG. 11 is a cross-sectional view of one embodiment of a resistor according to aspects of the present disclosure.

It is understood that additional steps can be provided before, during, and after the method 100, and some of the steps described below can be replaced or eliminated, for additional embodiments of the methods. It is further understood that additional features can be added in the semiconductor device 200, and some of the features described below can be replaced or eliminated, for additional embodiments of the semiconductor device 200. The present embodiment of method 100, and semiconductor device 200, provides a resistive structure for replacement gate technology, which simplifies the processing steps, reduces manufacturing costs, and exhibits increased resistivity while providing reduced area impact.

The method 100 and semiconductor device 200 provide a polysilicon resistor design for replacement gate technology. Referring to FIGS. 1 and 2, the method 100 begins at step 102 wherein a semiconductor substrate 210 is provided. The semiconductor substrate 210 may comprise an elementary semiconductor including silicon or germanium in crystal, polycrystalline, or an amorphous structure; a compound semiconductor including silicon carbide, gallium arsenide, gallium phosphide, indium phosphide, indium arsenide, and indium antimonide; or an alloy semiconductor including SiGe, GaAsP, AlInAs, AlGaAs, GaInAs, GaInP, and GaInAsP; or any other suitable material; and/or combinations thereof. In one embodiment, the alloy semiconductor substrate may have a gradient SiGe feature in which the Si and Ge composition change from one ratio at one location to another ratio at another location of the gradient SiGe feature. In another embodiment, the alloy SiGe is formed over a silicon substrate. In another embodiment, a SiGe substrate is strained. Furthermore, the semiconductor substrate may be a semiconductor on insulator, such as a silicon on insulator (SOI), or a thin film transistor (TFT). In some examples, the semiconductor substrate may include a doped epitaxial (epi) layer or a buried layer. In other examples, the compound semiconductor substrate may have a multilayer structure, or the silicon substrate may include a multilayer compound semiconductor structure.

The semiconductor substrate 210 includes at least one active region 211a and at least one passive region 211b. The active region 211a may include a variety of active microelectronic devices in various embodiments, such as P-channel field effect transistors (PFETs), N-channel field effect transistors (NFETs), metal-oxide semiconductor field effect transistors (MOSFETs), complementary metal-oxide semiconductor transistors (CMOSs), bipolar transistors, high voltage transistors, high frequency transistors, memory cells, other suitable active devices, and/or combinations thereof. The passive region 211b may include a variety of passive microelectronic devices in various embodiments, such as resistors, capacitors, inductors, fuses, other suitable components, and/or combinations thereof. The passive region 211b may further include at least one isolation region to define and electrically isolate the various active regions, such as field oxide regions. In the present embodiment, the method 100 will form a metal gate transistor within the active region 211a and a resistor within the passive region 211b.

The method 100 proceeds to step 104, wherein at least one isolation region 212 is formed on the semiconductor substrate 210 within the at least one passive region 211b. The isolation region 212 may utilize isolation technology, such as local oxidation of silicon (LOCOS) or shallow trench isolation (STI), to define and electrically isolate the various active regions 20. In the present embodiment, the isolation region 212 includes a STI, wherein the STI comprises a thickness, T. The thickness, T, may be between approximately 1500 Å and 4500 Å.

The isolation region 212, and in the present embodiment, the STI, may be formed by any suitable process. As one example, the formation of an STI may include patterning the semiconductor substrate by a photolithography process, etching a trench in the substrate (for example, by using a dry etching, wet etching, and/or plasma etching process), and filling the trench (for example, by using a chemical vapor deposition process) with a dielectric material, such as silicon oxide, silicon nitride, silicon oxynitride, fluoride-doped silicate glass (FSG), a low-K dielectric material, other suitable materials, and/or combinations thereof. In some embodiments, the filled trench may have a multi-layer structure such as a thermal oxide liner layer filled with silicon nitride or silicon oxide. In another example, the STI may be created using a processing sequence as follows: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon nitride.

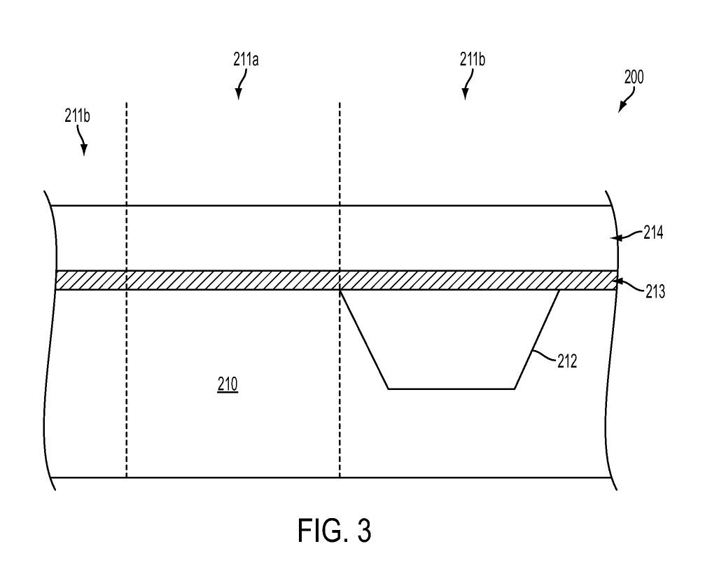

Referring to FIGS. 1 and 3, the method 100 proceeds to step 106 by forming a dielectric layer 213 and a polysilicon layer 214 over the semiconductor substrate 210.

Specifically, the dielectric layer 213 is disposed on the semiconductor substrate 210, over both the isolation region 212 and active region 211. The dielectric layer 213 may be any suitable dielectric material. The dielectric layer 213 may further include a multilayer structure comprising multiple dielectric materials. Preferably, the dielectric material will have relatively high integrity and low current leakage. In the present embodiment, the dielectric layer 213 comprises a high-K dielectric material. The high k material may be selected from metal oxides, metal nitrides, metal silicates, transition metal-oxides, transition metal-nitrides, transition metal-silicates, oxynitrides of metals, metal aluminates, zirconium silicate, zirconium aluminate, HfO₂, and/or combinations thereof. Examples of the dielectric material further include silicon oxide, silicon nitride, silicon oxynitride, hafnium oxide, zirconium oxide, titanium oxide, aluminum oxide, hafnium dioxide-alumina (HfO₂—Al₂O₃) alloy, other suitable high-K dielectric materials, and/or combinations thereof. In some embodiments, the dielectric layer 213 may comprise a layer of silicon dioxide and a layer of high-K dielectric material. Further, the dielectric layer 213 may be doped polycrystalline silicon with the same or different doping. The dielectric layer 213 may be formed using chemical vapor deposition (CVD), physical vapor deposition (PVD), atomic layer deposition (ALD), thermal oxide, plating, other suitable processes, and/or combinations thereof.

The gate electrode comprising the at least one gate layer 214 disposed over the gate dielectric layer 213. The gate electrode and electrode may comprise polycrystalline silicon; silicon-containing materials; germanium-containing materials; metal, such as aluminum, copper, tungsten, titanium, tantalum, titanium nitride, tantalum nitride, nickel silicide, cobalt silicide; other proper conductive materials; and combinations thereof. It is understood that in alternate embodiments, the gate layer 214 may comprise other suitable materials and may comprise multilayer structures. The gate electrode and electrode may be formed by CVD, PVD, ALD, thermal oxide, plating, other suitable processes, and/or combinations thereof.

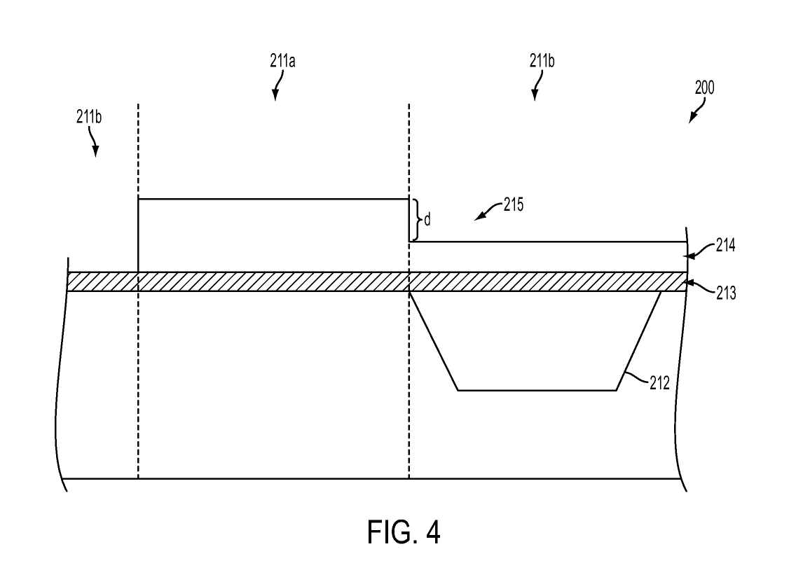

Next, in accordance to FIG. 1 and FIG. 4, in step 108 a recess 215 is formed in the portion of the polysilicon layer 214 that is above the isolation region 212. The recess 215 forms a distance, d, between a top surface of the portion of the polysilicon layer 214 in the active region 10, and a top surface of the portion of the polysilicon layer 214 above the isolation region 212. In some embodiments, d ranges between ten percent of the thickness of the isolation region 212 and 70% of the thickness of the isolation region 212 (i.e., 0.10 T≦d≦0.70 T). In some embodiments, d ranges between approximately 200 Å and 2000 Å.

The recess 215 in the polysilicon layer 214 may be formed by any suitable process. For example, forming the recess 215 may include pattering the semiconductor device 200 by a process, such as forming a photoresist layer over the portion of the polysilicon layer 214 above active region 10 of the semiconductor layer 210; patterning the photoresist layer by a photolithography process, wherein only the portion of the polysilicon layer 214 above the isolation region 212 is exposed; and etching a recess 215 in the portion of the polysilicon layer above isolation region 212. The etching process may use one or more etching steps, and may be dry etching, wet etching, and/or other etching methods (e.g., reactive ion etching). The etching process may be either purely chemical (plasma etching), purely physical (ion milling), and/or combinations thereof.

Thereafter, a polysilicon resistor implant process is performed only on the recessed polysilicon layer 214 (i.e., the portion of the polysilicon layer 214 above the isolation region 212). To accomplish the resistor implant, a photolithographic patterning step is used to form and pattern a mask over the portion of the polysilicon layer 214, and an ion or other implant step is performed over region 20. The polysilicon is then patterned further to define the polysilicon gate using a second photolithographic process as will be described below.

Referring to FIGS. 1 and 5 to 10, the method 100 proceeds to step 110 by forming at least one gate structure within active region 10; forming lightly doped regions within active region 10; and forming at least one resistive structure within passive region 20. The gate structure and the resistive structure may include a single layer or multiple layers. It is understood that a plurality of gate structures and resistive structures may be formed.

It is understood that the gate structure and the resistive structure may be formed simultaneously, utilizing the same processing steps and processing materials; the gate structure and the resistive structure may be formed independently of one another, utilizing varying processing steps and processing materials; or the gate structure and the resistive structure may be formed using a combination of simultaneous and independent processing steps and processing materials.

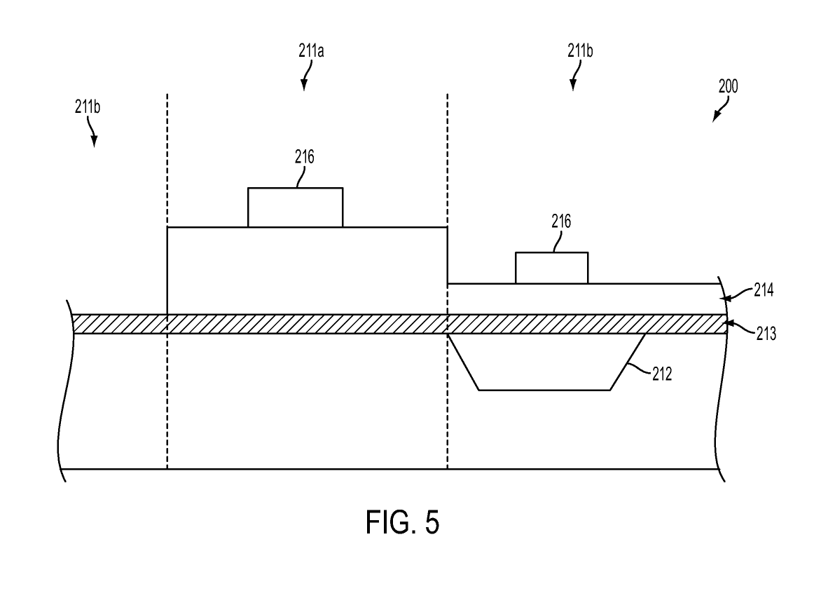

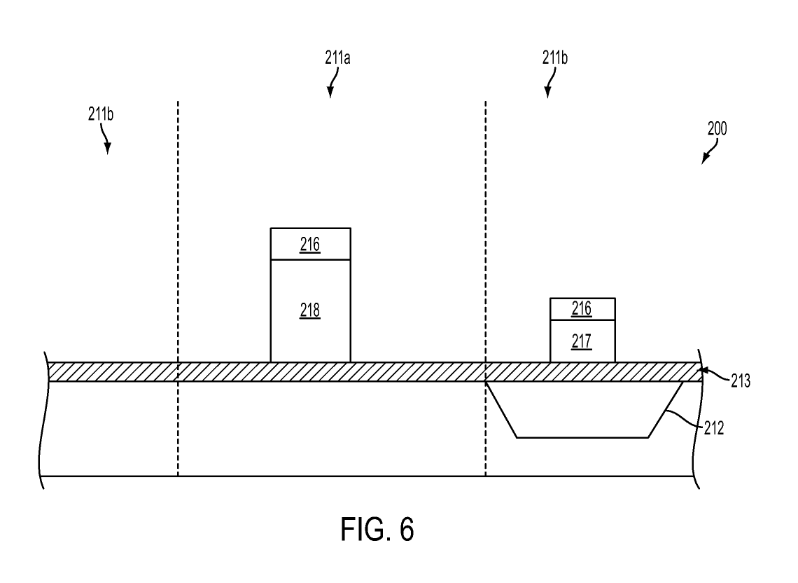

FIG. 5 shows how the processing steps that would define the size of the gate structure and the resistive structure. First, a photoresist layer 216 is formed over the polysilicon layer 214. The photoresist layer 216 should cover the portions of the polysilicon layer 214 that are in both the active region 10 and the passive region 20. Thereafter, a photolithographic process using a hard mask patterns the photoresist layer 216. As a result, a patterned photoresist layer 216 that defines the shape of the gate structure and the resistive structure remains on the polysilicon layer 214. Next, as FIG. 6 shows, the exposed portions of the polysilicon layer 214 are removed by methods such as dry etching, thus forming a resistive structure 217 above the isolation region 212 in the passive region 20, and a dummy polysilicon gate structure 218 in the active region 10. Subsequently, the patterned photoresist layer 216 is removed.

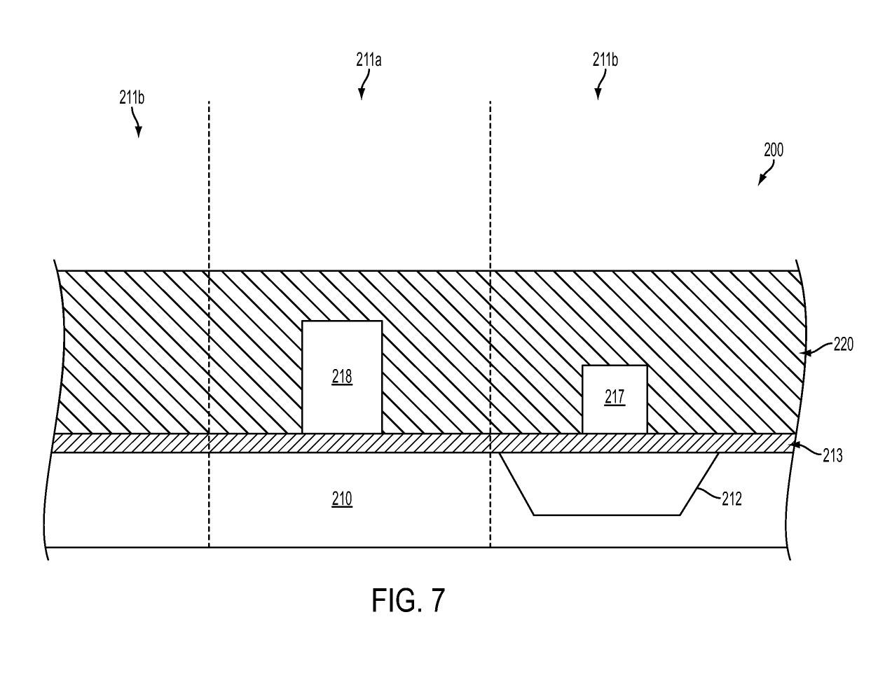

Next, FIG. 7 depicts the semiconductor device 200 in a cross-sectional view following additional processing. In FIG. 7, an inter-level or interlayer dielectric layer (ILD) 220 is formed over the polysilicon resist gate 217 and dummy gate 218 and extending to the surface of the semiconductor substrate 210. Note that, for simplicity, no gate sidewalls or gate spacers are shown in the figures on the polysilicon resist gate 217 and the dummy gate 218; however, in an actual process, gate sidewalls formed of oxides, nitrides, oxynitrides or combinations, and having one or several layers, may be formed on the sidewalls of the gate structures. Gate spacers may be formed to control implant spacing and provide self-alignment for source and drain diffusions, ion implants, tilt angle implants and the like. Sacrificial gate sidewall spacers may be used.

This ILD dielectric 220 may be formed, as non-limiting examples, of silicon dioxide, silicon nitride, silicon oxynitride, carbon containing dielectrics, TEOS, and combinations of these, and may be low-k, high-k or oxide dielectric, and may be formed of other known materials for ILD layers. Atomic level deposition (ALD), CVD, PECVD, PVD, thermal oxidation, or spin on steps may be used to form the ILD 220.

In this embodiment, as FIG. 7 illustrates, the ILD layer 220 is formed over the polysilicon resist gate 217 and dummy gate 218 and extending well above and beyond the top surfaces of these gate structures. As a result, the ILD layer 220 covers both the polysilicon resist gate 217 and dummy gate 218, so that both of these gate structures are embedded in the ILD layer 220.

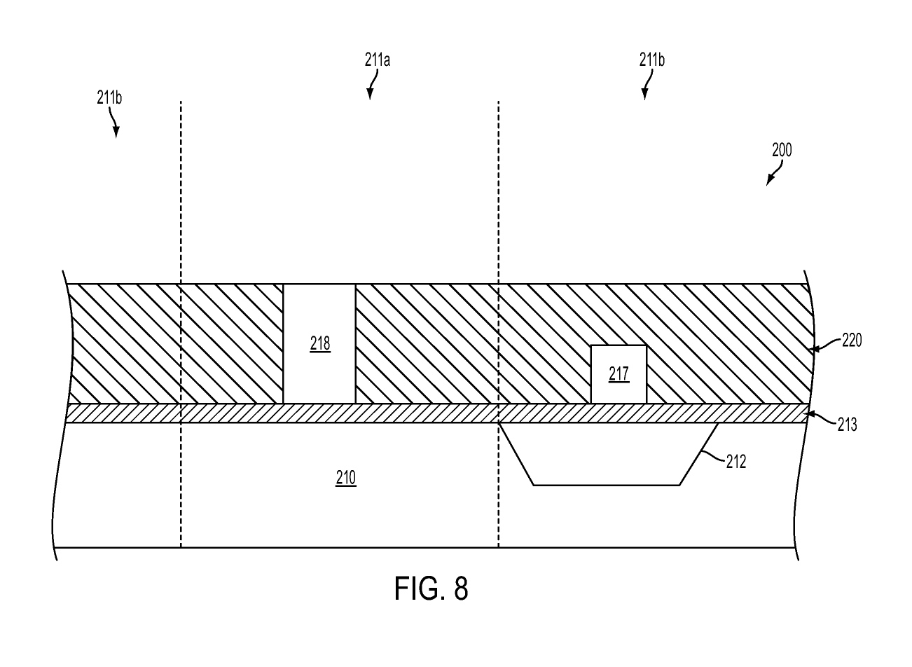

After the ILD deposition, as FIG. 8 shows, a chemical mechanical polishing (CMP) step “ILD CMP” may be performed to remove excess ILD material and planarize the top surface of the ILD with the top surfaces of the dummy gate 218, so the top surface of the dummy gate, is exposed at the surface of the ILD layer 220. However, because the top surface of the polysilicon resist gate 217 lays on a plane that is lower than that of the dummy gate 218, the polysilicon resist gate 217 continues to be embedded within the ILD layer 220 even after this CMP process. If CMP is not used in this ILD-removal step, then ILD chemical etching processes may be used instead.

Traditionally, a hardmask is formed over the isolation region 20 to protect the portion of the polysilicon resist gate 217 that is be exposed at the surface of the ILD layer 220. However, in this embodiment, because the polysilicon resist gate 217 is embedded entirely within the ILD layer 220, it does not need the hardmask to protect it from the subsequent exposures. The portion of the ILD layer 220 that is above the embedded polysilicon resist gate 217 essentially serves as a mask to protect the polysilicon resist gate 217. Polysilicon gate structure 218 in the active region, on the other hand, is now a “dummy gate” portion and, as shown in FIG. 8, is no longer being embedded in the ILD layer 220, and is exposed and ready to be removed by subsequent process steps.

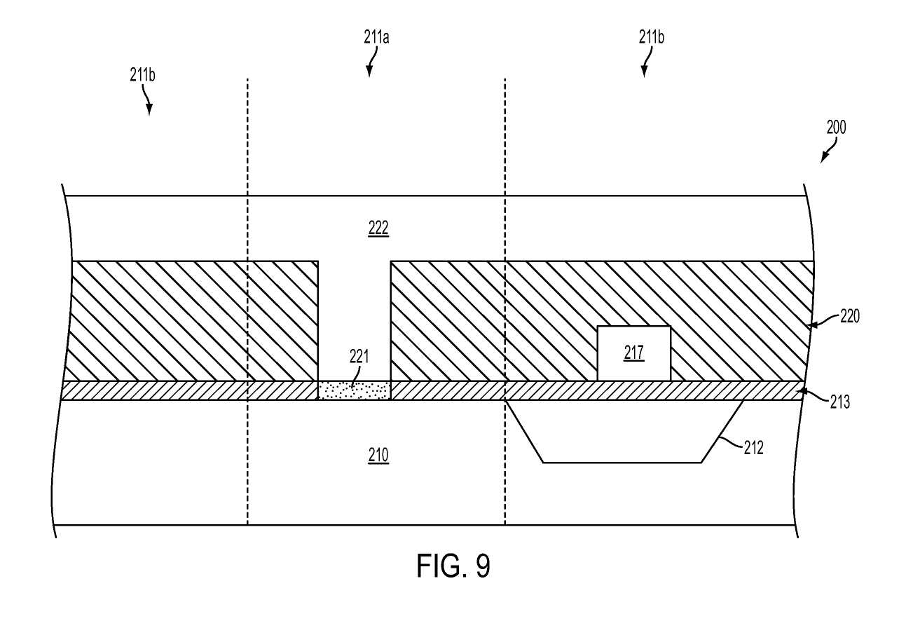

Next, FIG. 9 depicts the semiconductor device 200 in cross-section as shown in FIG. 8 following step 112 in which the polysilicon gate structures in the active regions are replaced with high-k metal gate material. In FIG. 9, the dummy gate 218 and the gate dielectric underlying dummy gate 218 have been removed, for example by the above described etching processes. A high-k dielectric 221 has been deposited and a layer of metal-containing gate material 222 has been formed in the trench in ILD 220 that remained after the dummy gate removal. The high-k dielectric 221 and the metal gate 222 have replaced the dummy gate 218 shown in FIG. 8.

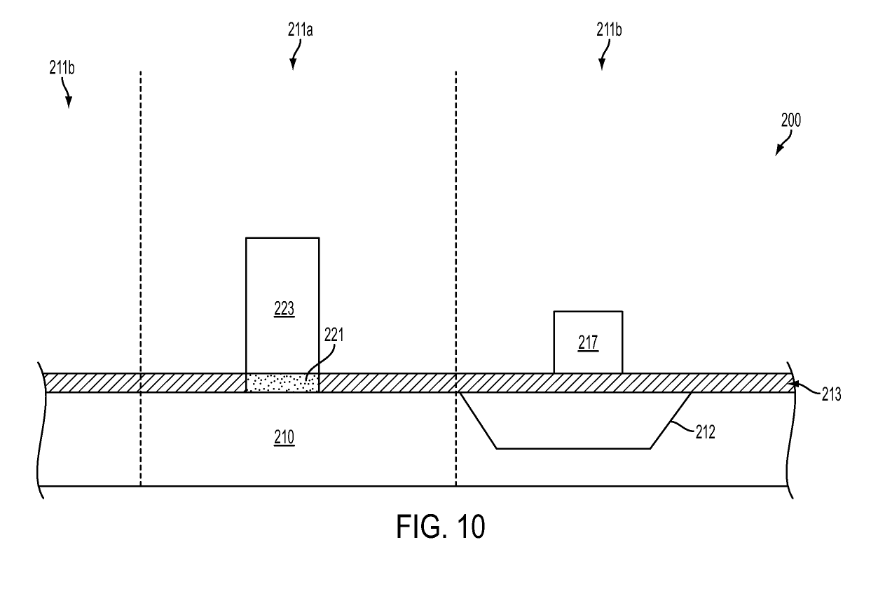

Several process steps were performed to transition from the intermediate stage shown in FIG. 9 to the cross-section of device 200 in FIG. 10. The dummy polysilicon gate 218 was removed by an etch process. The gate dielectric beneath the dummy polysilicon gate 218 was also removed. High-k gate dielectric material was deposited to form metal gate dielectric 223. A high-k dielectric has a dielectric constant, k, greater than that of silicon dioxide (oxide) dielectric, or greater than about 3.8. The material used can be any high-k gate dielectric; in one example, a hafnium based material is used, such as hafnium oxide. Other high-k gate dielectrics include, as non-limiting examples, hafnium silicate, zirconium silicate, hafnium dioxide and zirconium dioxide. The high-k dielectric may typically be deposited using atomic layer deposition (ALD) although the embodiments may include other processes for the dielectric deposition.

A metal gate 223 is provided in the opening in ILD 220 as shown in FIG. 10. This metal gate may be formed by deposition such as ALD or other deposition processes. Alternatively the metal gate may be formed by sputtering the metal seed layer, depositing the metal gate material by electroplating. A CMP process is then performed to remove excess metal from the surface of ILD 220, and to planarize ILD 220 and the surface of the metal gate 223 with the surface of polysilicon resist gate 217. Refractory metals including tungsten (W), titanium (Ti), and W/TiN layers may be used. Other metals may be used including tantalum (Ta), and molybdenum (Mo), and alloys of these may be used. Aluminum (Al) may be used. Multiple layers for the metal gate may be used, for example, a TiN layer may be used as a first layer in the metal gate 223 to adjust the work function of a high-k metal gate device, and partially fill the trench, and an aluminum conductor layer may then be deposited to complete the conductor layer. Barrier layers and diffusion layers may be used in forming the metal gate 223.

Thus, as shown in FIG. 11, device 200 contains both a high-k metal gate capacitor device with high-k dielectric, with the metal gate 223 forming the top plate of the capacitor, and a polysilicon capacitor having a top plate of gate that is doped polysilicon for a resistor, for example, over a gate dielectric. The embodiments thus allow both HKMG capacitors and polysilicon MOS capacitors to exist in the same area or region of the semiconductor substrate 210. Because the polysilicon resistor capacitors reduce the metal pattern density for CMP, the capacitors may be formed including the HKMG MOS capacitors, without CMP loading, and the CMP loading problems associated with previous approaches are reduced or eliminated.

As shown in FIG. 11, the gate spacers 224, are positioned on each side of the high-k metal gate structure 223 and polysilicon resistive gate 217, may comprise a dielectric material such as silicon nitride, silicon oxide, silicon carbide, silicon oxynitride, other suitable materials, or combinations thereof. In some embodiments, the gate spacers 224 may comprise a multilayer structure. The spacers may be formed by depositing the dielectric material by CVD, ALD, PVD, and/or other suitable processes and then etching.

Also, as FIG. 11 shows, the doped regions 230, 232 are formed in the semiconductor substrate 210 after the formation of the gate spacers 224. The doped regions 230, 232 may be doped n-type and/or p-type and may comprise various doping profiles.

The doped regions 230, 232 may be doped with p-type or n-type dopants. For example, the doped regions 230, 232 may be doped with p-type dopants, such as boron or BF₂. Alternatively, the doped regions 230, 232 may be doped with n-type dopants, such as phosphorus or arsenic. The doped regions 230, 232 may include a source and drain region. In step 114 the source and drain regions may be formed directly on the semiconductor substrate 210, in a P-well structure, in an N-well structure, in a dual-well structure, or using a raised structure. The source and drain regions may comprise various doping profiles and may be formed by a plurality of ion implantation processes. Alternate embodiments may have only one doped region or multiple doped regions. The doped regions 230, 232 are formed by any suitable process, such as ion implantation and/or a rapid thermal process (RTP) to activate the doped regions.

Optionally, in another embodiment, a recess is formed in the doped regions 230, 232, wherein the doped regions 230, 232 are recessed from a top surface of the semiconductor substrate 210. The recess may be formed by any suitable process. In some embodiments, the recess is a distance from a top surface of the semiconductor substrate 210 to a top surface of the doped regions 230, 232. In one example, the distances from the top surface of the semiconductor substrate of the semiconductor substrate 210 and the top surface of the doped regions 230, 232 is at least 250 Å. The doped regions 230, 232 may not include recess, making the top surface of the semiconductor substrate 210 level with the top surface of the doped regions 230, 232.

Also, as FIG. 11 illustrates, the polysilicon resistive gate structure 217, is doped. The electrode may be doped with p-type or n-type dopants. For example, the electrode may be doped with p-type dopants, such as boron or BF₂. Alternatively, the electrode may be doped with n-type dopants, such as phosphorus or arsenic. In some embodiments, the polysilicon resistive gate structure 217 may comprise doped polysilicon. In some embodiments, the polysilicon resistive gate structure 217 may comprise doped amorphous silicon. The electrode of the polysilicon resistive gate structure 217 may be doped by any suitable process including in-situ doping and/or ion implantation. In one example, the electrode may be doped while forming the doped regions 230, 232, such as performing a simultaneous ion implantation process. In other examples, the electrode may be doped independently from the doped regions 230, 232, such as independent photolithography patterning and etching processes to form the electrode and the doped regions 230, 232. Doping the electrode of the polysilicon resistive gate structure 217 independently may provide more flexibility in tuning the resistivity of the polysilicon resistive gate structure 217.

As discussed below, a salicidation process can also be additionally applied to form silicide regions in the doped regions 230, 232. Typically, a resistive structure is also exposed to the salicidation process, forming a silicide region in the resistive structure. However, a resistive structure including a silicide region exhibits lower than desirable resistance and results in larger than desirable area overhead. Such resistive structure poses additional disadvantages for analog circuits, such as radio frequency (RF) and mixed mode circuits, including the resistive structure being unable to provide precise impedance and capacitance matching.

Accordingly, a protection layer is required to be disposed over the polysilicon resistive gate structure 217. The protection layer may prevent a silicide region from forming in the polysilicon resistive gate structure 217. Preventing a silicide region from forming in polysilicon resistive gate structure 217 provides increased resistivity, resulting in lower area overhead. The protection layer may comprise any suitable material. In the present embodiment, the protection layer comprises a resist protection oxide (RPO). The RPO may be a dielectric layer, such as an oxide layer, a nitride layer, an oxy-nitride layer, other suitable layers, and/or combinations thereof. The RPO may also include one or many different layers. In the present embodiment, the RPO includes silicon oxide and/or silicon nitride. The protective layer may further comprise any suitable thickness. In some embodiments, the protective layer comprises a thickness from approximately 300 Å and 1500 Å. Further, the protection layer may be formed over the resistive structure by any suitable method.

Referring to FIGS. 1 and 11, in step 116 a silicide is formed in the doped regions 230, 232 to form doped silicide regions 233. It should be noted that the protection layer disposed over polysilicon resistive gate structure 217 prevents a silicide region from forming in the polysilicon resistive gate structure 217, resulting in increased resistivity of the polysilicon resistive gate structure 217, and accordingly reducing area overhead.

The silicide regions 233 may comprise materials such as nickel silicide (NiSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), other suitable materials, and/or combinations thereof. The materials utilized to create the silicide may be deposited using PVD such as sputtering and evaporation; plating; CVD such as plasma enhanced CVD (PECVD), atmospheric pressure CVD (APCVD), low pressure CVD (LPCVD), high density plasma CVD (HDPCVD) and atomic layer CVD (ALCVD); other suitable deposition processes; and/or combinations thereof. After deposition, the salicidation process may continue with a reaction between the deposited material and the doped regions at an elevated temperature that is selected based on the specific material or materials. This is also referred to as annealing, which may include a rapid thermal annealing process (RTP). The reacted silicide may require a one-step RTP or multiple step RTPs.

The method 100 and semiconductor device 200, as illustrated in FIGS. 1 to 11, provide a polysilicon resistive gate structure 217 comprising a polysilicon resistor for replacement gate technology. Such resistive structure, lying in a substantially different plane than the gate structure, provides a resistive structure with increased resistivity, lower overhead area, and improved impedance/capacitance matching. Moreover, the fact that the polysilicon resistive gate structure lies in a plane below that of the gate structure, the polysilicon resistive gate structure necessarily embeds in the ILD layer during the manufacturing process, thereby eliminating the need for a separate hard mask/photolithographic step when the dummy gate is being replaced by the high-k metal material to form the high-k metal gate.

Overall, the disclosed embodiments provide on or more of the following advantages: (1) fully compatible with present processes by porting the resistive structure directly and easily; (2) the resistive structure leaves a small foot-print (i.e., the resistive structure has a higher resistivity resulting in a smaller area); (2) small variation; (3) better linearity (e.g., small temperature and voltage coefficients); (4) small mismatch; (5) the benefits in variation, linearity, and mismatch also lead to smaller die size; (6) reduced noise coupling, the resistive structures disposed over the isolation regions result in very low coupling capacitance; (7) an additional masking layer is needed; (8) higher applicable frequency (e.g., the resistive structure virtually forms a RC ladder with lower cutoff frequency); (9) impedance and capacitance matching concerns are eliminated; (10) lower programming voltages; (11) save cost by eliminating the need for an additional photolithographic during the formation of a high-k metal gate. It is understood that steps and features from method 100 and semiconductor device 200 may be utilized interchangeably to provide various methods and semiconductor devices in order to obtain any of the above advantages.

In summary, a semiconductor device and method is provided that includes a resistive structure that remedies the issues addressed above. In one embodiment, a semiconductor device comprises a semiconductor substrate; an active region of the substrate, wherein the active region includes at least one transistor; and a passive region of the substrate, wherein the passive region includes at least one resistive structure disposed on an isolation region, the at least one resistive structure in a lower plane than the at least one transistor. The semiconductor device may further comprise a polish stop layer disposed over the semiconductor substrate between the at least one transistor and the at least one resistive structure.

In some embodiments, the isolation region comprises a shallow trench isolation (STI). A distance between a top surface of the isolation region and a top surface of the semiconductor substrate may be between approximately 200 Å and 2000 Å. A distance between a top surface of the at least one resistive structure and a top surface of the at least one transistor may be at least 250 Å.

In some embodiments, the at least one transistor comprises a metal gate transistor. In some embodiments, the at least one resistive structure comprises at least one of a resistor or an e-Fuse. In some embodiments, the at least one resistive structure comprises silicon. In some embodiments, the at least one resistive structure comprises at least one of a discrete resistor or a discrete e-Fuse, at least one of a resistor array or an e-Fuse array, and/or combinations thereof. In some embodiments, the at least one resistive structure comprises a shape including at least one of a line, dog bone, or rectangle. The at least one resistive structure may comprise at least one of doped polysilicon or doped amorphous silicon. Also, the at least one resistive structure may be doped by at least one of in-situ or ion implantation.

In one embodiment, a semiconductor device comprises a semiconductor substrate; an active region of the substrate, wherein the active region includes at least one transistor; and a passive region of the substrate, wherein the passive region includes at least one resistive structure disposed on an isolation region, the isolation region having a concave surface. The at least one resistive structure may be in a lower plane than the at least one transistor. Further, the semiconductor device may comprise a polish stop layer disposed over the semiconductor substrate between the at least one transistor and the at least one resistive structure. A distance between a top surface of the at least one resistive structure and a top surface of the at least one transistor may be at least 250 Å.

In some embodiments, the at least one transistor comprises a metal gate transistor. In some embodiments, the at least one resistive structure comprises at least one of a silicon resistor or a silicon e-Fuse. In some embodiments, the at least one resistive structure comprises at least one of a discrete resistor or a discrete e-Fuse, a resistor array or an e-Fuse array, and/or combinations thereof. In some embodiments, the at least one resistive structure comprises a shape including at least one of a line, dog bone, or rectangle. The at least one resistive structure may comprise at least one of doped polysilicon or doped amorphous silicon. Also, the at least one resistive structure may be doped by at least one of in-situ or ion implantation.

In another embodiment, a semiconductor device comprises a semiconductor substrate including at least one active region and at least one passive region; a gate structure disposed over the semiconductor substrate within the at least one active region; and a resistive structure disposed over an isolation region on the semiconductor substrate within the at least one passive region, wherein the resistive structure is in a lower plane than the gate structure. The semiconductor device may further comprise at least one doped region adjacent each side of the gate structure, the at least one doped region including a recess, wherein there is a distance between a top surface of the semiconductor substrate and a top surface of the at least one doped region; and a silicide region in the at least one doped region. Also, in some embodiments, the semiconductor device further comprises a polish stop layer that overlies the semiconductor device between the gate structure and the resistive structure.

In some embodiments, the isolation region includes a recess, wherein a top surface of the gate structure is higher than a top surface of the resistive structure. In some embodiments, a protective layer overlies the resistive structure. The protective layer may prevent the resistive structure from being exposed to a salicidation process and forming a silicide region in the resistive structure. The protective layer may comprise a resist protective oxide. In some embodiments, the resist protective oxide including at least one of silicon oxide or silicon nitride. In some embodiments, the resist protective oxide comprises a thickness between approximately 300 Å and 1500 Å.

In one embodiment, a method for forming a semiconductor device comprises providing a semiconductor substrate; forming at least one gate structure over the semiconductor substrate and at least one resistive structure over an isolation region on the semiconductor substrate, wherein the resistive structure lies in a lower plane than the gate structure; forming at least one doped region in the semiconductor substrate; and forming a silicide in the at least one doped region. The method may further comprise forming a protection layer over the resistive structure before forming the silicide in the at least one doped region. In some embodiments, the method further comprises forming a recess in the isolation region, and/or forming a recess in the at least one doped region prior to forming a silicide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device, comprising:
providing a semiconductor substrate that contains at least one active region and one isolation region;
forming at a polysilicon gate structure in the active region and a polysilicon gate structure in the isolation region;
forming an interlayer dielectric layer over the semiconductor substrate so that the polysilicon gate structures in both the active and isolation regions are embedded in the interlayer dielectric layer;
removing a portion of the interlayer dielectric layer so that the top surface of the polysilicon gate structure in the active region is exposed at the surface of the interlayer dielectric layer, while the polysilicon gate structure in the isolation region continues to be embedded in the interlayer dielectric layer;
forming a high-k dielectric layer in the active region, the high-k dielectric layer in contact with the semiconductor substrate; and
replacing the polysilicon gate structure in the active region with a high-k metal formed over and in contact with the high-k dielectric layer while the polysilicon gate structure in the isolation region is embedded in the interlayer dielectric layer.

2. The method of claim 1, wherein a top surface of the polysilicon gate structure in the isolation region is on a lower plane than a top surface of the polysilicon gate structure in the active region.

3. The method of claim 2, further comprising forming a silicide in the at least one doped region.

4. The method of claim 2, further comprising forming a recess in the isolation region.

5. The method of claim 2, further comprising forming a recess in the at least one doped region prior to forming a silicide.

6. The method of claim 1, further comprising forming at least one doped region in the semiconductor substrate.

7. A semiconductor device comprising:
a semiconductor substrate having an isolation region and an active region disposed therein;
a high-k metal gate transistor disposed over the active region of the semiconductor substrate, the high-k metal gate transistor having a high-k dielectric layer in contact with the semiconductor substrate and a high-k metal formed over and in contact with the high-k dielectric layer;
a polysilicon resistor disposed over isolation region of the semiconductor substrate; and
an interlayer dielectric layer is disposed over the semiconductor substrate, such that a top surface of the metal gate transistor is equal or above a top surface of the interlayer dielectric layer and that a top surface of the polysilicon resistor is below the top surface of the interlayer dielectric layer.

8. The semiconductor device of claim 7, wherein the isolation region comprises a shallow trench isolation (STI).

9. The semiconductor device of claim 7, wherein a distance between a top surface of the polysilicon resistor and a top surface of the metal gate transistor is at least 300 Å.

10. The semiconductor device of claim 7, wherein the polysilicon resistor comprises doped polysilicon.

11. The semiconductor device of claim 7, wherein the polysilicon resistor is doped at least one of in-situ or ion implantation.

12. The semiconductor device of claim 7, wherein the metal gate transistor comprises a high-k gate dielectric material and a metal gate material.

13. The semiconductor device of claim 12, wherein the high-k gate dielectric material has a dielectric constant greater than that of silicon dioxide dielectric.

14. The semiconductor device of claim 12, wherein the metal gate material comprises of refractory metals such as tungsten, titanium, tantalum, molybdenum, and alloys thereof.

15. The semiconductor device of claim 7, further comprising at least one doped region adjacent each side of the gate structure.

16. The semiconductor device of claim 15, wherein a silicide region is in the at least one doped region.
